(19) United States
(12) Patent Application Publication
(10) Pub. No.: US 2026/0196934 A1
(43) Pub. Date: Jul. 9, 2026

(54) VOLTAGE CONVERTER, METHOD OF OPERATING VOLTAGE CONVERTER, AND STORAGE DEVICE INCLUDING POWER MANAGEMENT INTEGRATED CIRCUIT

(71) Applicant: Samsung Electronics Co., Ltd., Suwon-si (KR)

(72) Inventors: Yongjin KWON, Suwon-si (KR); Jaehyun PARK, Suwon-si (KR); Hongseok SHIN, Suwon-si (KR); Sumin PARK, Suwon-si (KR); Sun-Kyu LEE, Suwon-si (KR); Seongwon JOO, Suwon-si (KR)

(73) Assignee: Samsung Electronics Co., Ltd., Suwon-si (KR)

(21) Appl. No.: 19/278,255

(22) Filed: Jul. 23, 2025

(30) Foreign Application Priority Data
Jan. 9, 2025 (KR) 10-2025-0003629

(51) Int. Cl. H02M 3/158; H02M 1/32

(52) U.S. Cl. CPC H02M 3/158; H02M 1/32

(57) ABSTRACT

Disclosed is a voltage converter. The voltage converter includes a first switch between an input voltage node and a switching node, the input voltage node configured to receive an input voltage, a second switch between the switching node and a ground node, the ground node configured to receive a ground voltage, an inductor between the switching node and an output node, a capacitor between the inductor and the ground node, a control circuit configured to control the first switch and the second switch to output an output voltage through the output node, the output voltage being lower than the input voltage, and a protection circuit configured to turn off the first switch in response to the first switch being turned on for a period of time that is longer than a desired period of time.

### CROSS-REFERENCE TO RELATED APPLICATIONS

This application claims priority under 35 U.S.C. § 119 to Korean Patent Application No. 10-2025-0003629 filed on Jan. 9, 2025, in the Korean Intellectual Property Office, the disclosures of which are incorporated by reference herein in their entireties.

### BACKGROUND

Various example embodiments of the present inventive concepts described herein relate to an electronic device, and more particularly, relate to a voltage converter having improved stability, a method of operating the voltage converter, and a storage device including a power management integrated circuit.

An electronic device may receive one input voltage from a voltage source. The electronic device may operate using various internal voltages, the levels of which are different from those of the input voltage. To generate various internal voltages, the electronic device may include a voltage converter that converts an input voltage into an internal voltage.

The voltage converter may include a buck converter. The buck converter may convert an input voltage to an output voltage that is lower than the input voltage. For example, if the internal operating voltage of the electronic device is lower than the input voltage, the electronic device may include a buck converter. As low power characteristics become more important in electronic devices, the operating voltage of the electronic devices has continuously decreased. Accordingly, many electronic devices may include buck converters.

A buck converter is configured to supply an internal voltage to internal circuits of an electronic device. When the internal voltage supplied by the buck converter is overcharged to a high voltage, the internal circuits may be damaged. Therefore, it may be beneficial to provide a storage device including a voltage converter having improved stability, a method of operating the voltage converter, and a storage device including a power management integrated circuit capable of preventing (or reducing a likelihood of) an internal voltage from being overcharged to a high voltage.

### SUMMARY

Various example embodiments of the present inventive concepts provide a voltage converter, a method of operating the voltage converter, and a storage device including a power management integrated circuit, which provide improved stability by preventing an internal voltage from being overcharged to a high voltage (or by reducing a probability of an internal voltage being overcharged to a high or particular voltage).

According to some example embodiments, a voltage converter includes a first switch between an input voltage node and a switching node, the input voltage node configured to receive an input voltage, a second switch between the switching node and a ground node, the ground node configured to receive a ground voltage, an inductor between the switching node and an output node, a capacitor between the inductor and the ground node, a control circuit configured to control the first switch and the second switch to output an output voltage through the output node, the output voltage being lower than the input voltage, and a protection circuit configured to turn off the first switch in response to the first switch being turned on for a period of time that is longer than a desired period of time.

According to some example embodiments, a method of operating a voltage converter includes controlling, by a control circuit of the voltage converter, a first switch and a second switch to convert an output voltage supplied to a first terminal of the first switch into an output voltage output to an output node between an inductor and a capacitor, and turning off, by a protection circuit of the voltage converter, the first switch in response to an overcharge of the output voltage being detected.

According to some example embodiments, a storage device includes a nonvolatile memory device, a storage controller that controls the nonvolatile memory device, and a power management integrated circuit (PMIC) configured to supply power to the storage controller, wherein the PMIC includes a first switch between an input voltage node and a switching node, the input voltage node configured to receive an input voltage, a second switch between the switching node and a ground node, the ground node configure to receive a ground voltage, an inductor between the switching node and an output node, a capacitor between the inductor and the ground node, a control circuit configured to control the first switch and the second switch to output an output voltage through the output node, the output voltage being lower than the input voltage, and a protection circuit configured to turn off the first switch in response to the first switch being turned on for a period of time that is longer than a desired period of time.

According to some example embodiments, a method of operating a charging circuit includes dividing, by a first comparison circuit, a switching voltage, outputting, by the first comparison circuit, a first control signal to a charging circuit based on the divided switching voltage and a first reference voltage, providing, by the charging circuit, a first voltage to a second comparison circuit based on the divided switching voltage and the first reference voltage, outputting, by the second comparison circuit, a second control signal to a level shifter based on the first voltage and a second reference voltage, and outputting, by the level shifter, a third control signal to a logic gate circuit based on the first voltage and the second reference voltage.

In some example embodiments, the first comparison circuit is configured to output the first control signal having a low level in response to the divided switching voltage being equal of higher than the first reference voltage.

In some example embodiments, the first comparison circuit is configured to output the first control signal having a high level in response to the divided switching voltage being lower than the first reference voltage.

In some example embodiments, the second comparison circuit is configured to output the second control signal having a high level in response to the first voltage reaching the second reference voltage.

According to some example embodiments of the present inventive concepts, overcharge is detected in the output voltage of the voltage converter, and when overcharge is detected, charging is blocked. Accordingly, a voltage converter having improved stability for preventing overcharge from occurring in the output voltage of the voltage converter (or for reducing a probability that overcharge occurs in the output voltage of the voltage converter), a method of operating the voltage converter, and a storage device including a power management integrated circuit are provided.

### BRIEF DESCRIPTION OF THE FIGURES

The above and other objects and features of the present inventive concepts will become apparent by describing in detail some example embodiments thereof with reference to the accompanying drawings.

FIG. 1 illustrates a voltage converter according to some example embodiments.

FIG. 2 illustrates an example of a method of operating a voltage converter according to some example embodiments.

FIG. 3 illustrates a first example of waveforms of signals of a voltage converter.

FIG. 4 illustrates a second example of waveforms of signals of a voltage converter.

FIG. 5 illustrates a third example of waveforms of signals of a voltage converter.

FIG. 6 illustrates a voltage divider and a first charging circuit according to some example embodiments.

FIG. 7 illustrates a second charging circuit, a second comparison circuit, a third comparison circuit, and a level shifter according to some example embodiments.

FIG. 8 illustrates an example of a method of operating a second charging circuit, a second comparison circuit, a third comparison circuit, and a level shifter according to some example embodiments.

FIG. 9 illustrates an example of a logic gate according to some example embodiments.

FIG. 10 illustrates a storage device according to some example embodiments.

FIG. 11 illustrating an example of a method of operating a storage device according to some example embodiments.

### DETAILED DESCRIPTION

Hereinafter, some example embodiments of the present inventive concepts will be described clearly and in detail so that those skilled in the art may easily carry out some example embodiments of the present inventive concepts.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to the other elements and/or properties thereof. Elements and/or properties thereof that are “the same” or “equal” to other elements and/or properties thereof will be understood to include elements and/or properties thereof that are identical to, the same as, or equal to the other elements and/or properties thereof within manufacturing tolerances and/or material tolerances (e.g., ±10%). Elements and/or properties thereof that are identical, the same, and/or equal as other elements and/or properties thereof may be structurally the same or substantially the same, functionally the same or substantially the same, and/or compositionally the same or substantially the same thereof.

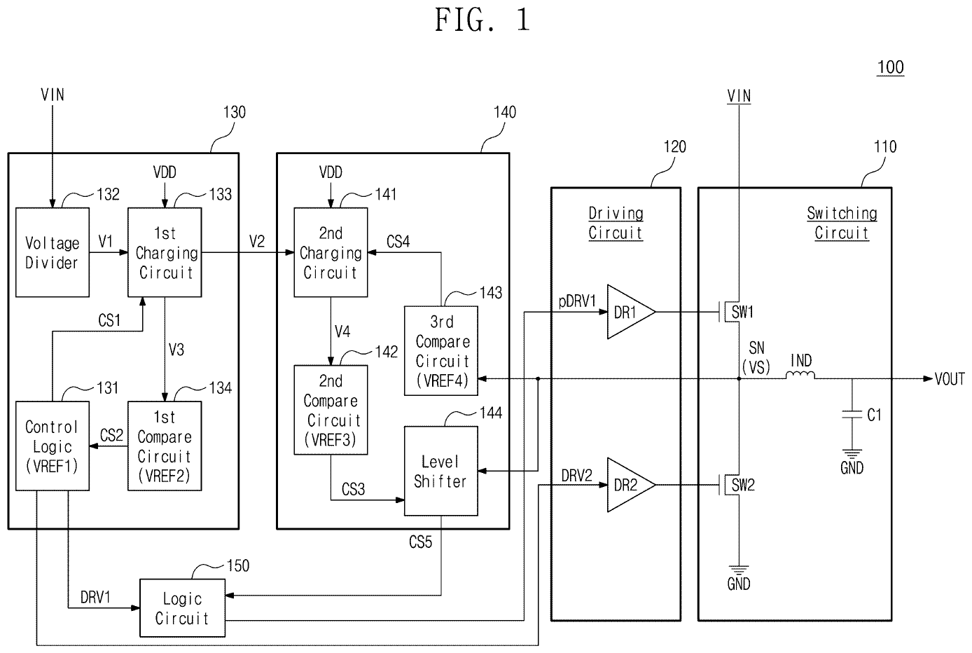

FIG. 1 illustrates a voltage converter 100 according to some example embodiments. The voltage converter 100 may receive an input voltage VIN at an input voltage node from an external device, and convert the input voltage VIN into an output voltage VOUT to output the output voltage VOUT. For example, the voltage converter 100 may be a buck converter that reduces (or that is configured to step down) the input voltage VIN and outputs it (e.g., the reduced voltage) as the output voltage VOUT.

Referring to FIG. 1, the voltage converter 100 may include a switching circuit 110, a driving circuit 120, a control circuit 130, a protection circuit 140, and a logic gate 150 (also referred to as the logic circuit 150).

The switching circuit 110 may receive the input voltage VIN from an external device. The switching circuit 110 may convert the input voltage VIN into the output voltage VOUT under the control of the control circuit 130 and the logic gate 150. For example, the switching circuit 110 may step down the input voltage VIN and output it (e.g., the stepped down voltage) as the output voltage VOUT.

The switching circuit 110 may include a first switch SW1, a second switch SW2, an inductor IND, and a first capacitor C1.

The first switch SW1 may be connected between an input node to which the input voltage VIN is supplied and a switching node SN. For example, the first switch SW1 may include an NMOS transistor, but example embodiments are not limited thereto. The second switch SW2 may be connected between the switching node SN and a ground node to which a ground voltage GND is supplied. For example, the second switch SW2 may include an NMOS transistor, but example embodiments are not limited thereto.

The inductor IND may be connected between the switching node SN and an output node from which the output voltage VOUT is output. The first capacitor C1 may be connected between the output node from which the output voltage VOUT is output and the ground node from which the ground voltage GND is supplied. For example, the voltage of the switching node SN may be a switching voltage VS.

The driving circuit 120 may include a first driver DR1 that receives a first protected driving signal pDRV1 from the logic gate 150, and a second driver DR2 that receives a second driving signal DRV2 from the control circuit 130.

The first driver DR1 may control the first switch SW1 in response to the first protected driving signal pDRV1. The second driver DR2 may control the second switch SW2 in response to the second driving signal DRV2. For example, the first driver DR1 may be biased (or may be configured) to receive or output a signal that transitions between the switching voltage VS and the input voltage VIN. The second driver DR2 may be biased (or may be configured) to receive or output a signal that transitions between the ground voltage GND and the switching voltage VS.

The control circuit 130 may receive the input voltage VIN from an external device and store information about a target level of the output voltage VOUT. Additionally or alternatively, the control circuit 130 may further receive the output voltage VOUT, the switching voltage VS, or the amount of current of the inductor IND (or the control circuit 130 may further receive information about the output voltage VOUT, the switching voltage VS, and/or the amount of current of the inductor IND). The control circuit 130 may generate a first driving signal DRV1 and the second driving signal DRV2 based on the information about the input voltage VIN and the target level, or further based on the output voltage VOUT, the switching voltage VS, or an amount of current in the inductor IND (or further based on the information about the output voltage VOUT, the switching voltage VS, and/or an amount of current in the inductor IND).

For example, the control circuit 130 may control the rise of the output voltage VOUT, for example, the charging of the inductor IND or the first capacitor C1, by using the first driving signal DRV1. The control circuit 130 may control the rise of the output voltage VOUT, for example, the discharge of the inductor IND or the first capacitor C1, by using the second driving signal DRV2.

The control circuit 130 may include control logic 131, a voltage divider 132, a first charging circuit 133, and a first comparison circuit 134.

The control logic 131 may store a first reference voltage VREF1 as the information about the target level of the output voltage VOUT. The control logic 131 may perform a pulse width modulation operation for the first driving signal DRV1 and the second driving signal DRV2 by comparing the output voltage VOUT, the switching voltage VS, or the current amount (or the voltage corresponding to the current amount) of the inductor IND with the first reference voltage VREF1. For example, the control logic 131 may control the switching circuit 110 to reduce (or step down) the input voltage VIN to the target level of the output voltage VOUT by controlling a time period during which the inductor IND or the first capacitor C1 is charged and a time period during which it (e.g., the inductor IND or the first capacitor C1) is discharged.

For example, the control logic 131 may output the second driving signal DRV2 that turns off the second switch SW2 and output the first driving signal DRV1 that turns on the first switch SW1 when (or in response to) the output voltage VOUT, the switching voltage VS, or the amount of current in the inductor IND changes from a level higher than the first reference voltage VREF1 to a level equal to or lower than the first reference voltage VREF1. The control logic 131 may invert the first driving signal DRV1 and the second driving signal DRV2 in response to a first control signal CS1.

The control logic 131 may be configured to further output the first control signal CS1. The first control signal CS1 may be used to measure the timing at which the control circuit 130 controls the first driving signal DRV1 to a level at which the first switch SW1 is turned on and then controls the first driving signal DRV1 to a level at which the first switch SW1 is turned off. The control logic 131 may activate the first control signal CS1 after controlling the first driving signal DRV1 to be a level that turns on the first switch SW1. The control logic 131 may control the first driving signal DRV1 to be a level that turns off the first switch SW1, and then deactivate the first control signal CS1.

The voltage divider 132 may receive the input voltage VIN from an external device. The voltage divider 132 may divide the input voltage VIN to generate a first voltage V1. For example, the voltage divider 132 may divide the input voltage VIN to generate the first voltage V1 so as to correspond to the design purpose of the control circuit 130, the level of the input voltage VIN and the level of the output voltage VOUT.

The first charging circuit 133 may receive the first control signal CS1 from the control logic 131 and the first voltage V1 from the voltage divider 132. The first charging circuit 133 may receive a power voltage VDD from an external device or through internal wiring. The first charging circuit 133 may measure the time period during which the first driving signal DRV1 turns on the first switch SW1 based on the first voltage V1 and the first control signal CS1.

For example, the first charging circuit 133 may generate a second voltage V2 by using the first voltage V1. The first charging circuit 133 may discharge an internal capacitor while the first control signal CS1 is inactive. The first charging circuit 133 may charge an internal capacitor by using the second voltage V2 while the first control signal CS1 is activated in order to generate a third voltage V3. The level of the third voltage V3 may refer to the length of the time period during which the capacitor inside the first charging circuit 133 is charged, for example, the length of the time period during which the inductor IND or the first capacitor C1 of the switching circuit 110 is charged.

The first comparison circuit 134 may receive the third voltage V3 from the first charging circuit 133. The first comparison circuit 134 may compare the third voltage V3 with a second reference voltage VREF2. In some example embodiments, when the third voltage V3 is equal to or higher than the second reference voltage VREF2, the first comparison circuit 134 may output a high level (or low level) voltage and/or signal. In some example embodiments, when the third voltage V3 is lower than the second reference voltage VREF2, the first comparison circuit 134 may output a low level (or high level) voltage and/or signal.

For example, the first control signal CS1 may be generated based on various operations associated with a pulse width modulation operation within the control logic 131. The first control signal CS1 may contain the result of an unintended malfunction or noise. Therefore, the level of the first control signal CS1 may not be adjusted as intended, and an error may occur in the voltage converter 100 due to the abnormal level of the first control signal CS1.

The protection circuit 140 may receive the second voltage V2 from the control circuit 130 and the switching voltage VS from the switching circuit 110. Based on the second voltage V2 and the switching voltage VS, a fifth control signal CS5 may be generated. The fifth control signal CS5 may be a signal indicating that the inductor IND or the first capacitor C1 is overcharged. For example, the protection circuit 140 may detect that the inductor IND or the first capacitor C1 is overcharged, and thus, the output voltage VOUT increases excessively (or the output voltage VOUT may increase to a level higher than a desired voltage level).

The protection circuit 140 may include a second charging circuit 141, a second comparison circuit 142, a third comparison circuit 143, and a level shifter 144.

The second charging circuit 141 may receive the second voltage V2 from the first charging circuit 133 of the control circuit 130. The second charging circuit 141 may receive the power voltage VDD from an external device or through internal wiring. The second charging circuit 141 may discharge the internal capacitor while a third control signal CS3 is inactive. The second charging circuit 141 may charge an internal capacitor by using the second voltage V2 while the third control signal CS3 is activated, thereby generating a fourth voltage V4. The level of the fourth voltage V4 may indicate the length of the time period during which the capacitor inside the second charging circuit 141 is charged.

The second comparison circuit 142 may receive the fourth voltage V4 from the second charging circuit 141. The second comparison circuit 142 may compare the fourth voltage V4 with a third reference voltage VREF3. In some example embodiments, when the fourth voltage V4 is equal to or higher than the third reference voltage VREF3, the second comparison circuit 142 may output the third control signal CS3 of a high level (or low level). In some example embodiments, when the fourth voltage V4 is lower than the third reference voltage VREF3, the second comparison circuit 142 may output the third control signal CS3 of a low level (or high level).

The third comparison circuit 143 may receive the switching voltage VS from the switching circuit 110. The third comparison circuit 143 may compare the switching voltage VS (or a voltage derived from the switching voltage VS) with a fourth reference voltage VREF4. In some example embodiments, when the switching voltage VS (or a voltage derived from the switching voltage VS) is equal to or higher than the fourth reference voltage VREF4, the third comparison circuit 143 may output the fifth control signal CS5 (or the fourth control signal CS4) of a high level (or low level). In some example embodiments, when the switching voltage VS (or a voltage derived from the switching voltage VS) is lower than the fourth reference voltage VREF4, the third comparison circuit 143 may output a fourth control signal CS4 of a low level (or a high level). For example, the fourth reference voltage VREF4 may be set close to the center of the swing of the switching voltage VS (or a voltage derived from the switching voltage VS).

The level shifter 144 may receive the third control signal CS3 from the second comparison circuit 142. The level shifter 144 may receive the switching voltage VS from the switching circuit 110. The level shifter 144 may convert the levels (e.g., a high level and a low level) of the third control signal CS3 by using the switching voltage VS to generate the fifth control signal CS5.

The logic gate 150 may receive the first driving signal DRV1 from the control circuit 130 and the fifth control signal CS5 from the protection circuit 140. The logic gate 150 may perform a logic operation of the first driving signal DRV1 and the fifth control signal CS5 to generate the first protected driving signal pDRV1. For example, the logic gate 150 may perform an AND operation of the first driving signal DRV1 and the fifth control signal CS5.

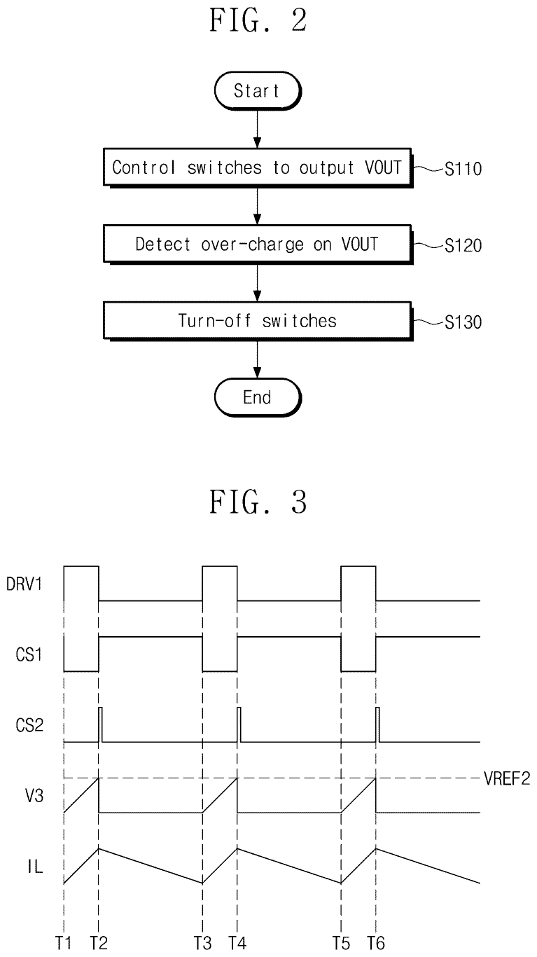

FIG. 2 illustrates an example of a method of operating the voltage converter 100 according to some example embodiments. Referring to FIGS. 1 and 2, in operation S110, the voltage converter 100 may control switches to output the output voltage VOUT. For example, the control circuit 130 may reduce (or step down) the input voltage VIN to generate the output voltage VOUT by controlling the first switch SW1 and the second switch SW2 of the switching circuit 110.

In operation S120, the voltage converter 100 may detect overcharge of the output voltage. For example, when a malfunction occurs or noise occurs in the control circuit 130, a malfunction may occur in which the first switch SW1 of the switching circuit 110 is not turned off after being turned on. A malfunction in which the turn-on state of the first switch SW1 is maintained may be called on-stuck. In some example embodiments, when an on-stuck occurs, the inductor IND or the first capacitor C1 may be overcharged through the first switch SW1, and an overvoltage may occur in which the output voltage VOUT becomes higher than the target voltage.

For example, overvoltage, in which the inductor IND or the first capacitor C1 is overcharged and the output voltage VOUT becomes higher than the target voltage, may cause damage to the circuit receiving the output voltage. The protection circuit 140 may be configured to detect overcharge or overvoltage at a level that does not cause damage to a circuit receiving the output voltage VOUT without interfering with the normal operation of the control circuit 130 controlling the first switch SW1 and the second switch SW2.

In operation S130, the voltage converter 100 may turn off the switches. For example, when overcharge or overvoltage is detected, the protection circuit 140 may control the first switch SW1 of the switching circuit 110 to be turned off, thereby preventing overcharge or overvoltage (or thereby avoiding/mitigating an overcharge and/or an overvoltage, or thereby reducing a probability of an overcharge and/or an overvoltage occurring).

For example, when the first switch SW1 is turned off by the protection circuit 140, the control circuit 130 may stop the operation of the voltage converter 100. By stopping the operation of the voltage converter 100, the circuit receiving the output voltage VOUT may be prevented from being damaged (or by stopping the operation of the voltage converter 100, damage to the circuit receiving the output voltage VOUT may be avoided/mitigated, or a probability of damaging the circuit receiving the output voltage VOUT may be reduced).

FIG. 3 illustrates a first example of the waveforms of signals of the voltage converter 100. For example, an example in which the protection circuit 140 does not operate and the control circuit 130 operates normally is illustrated in FIG. 3.

Referring to FIGS. 1 and 3, at a first time point T1, the control circuit 130 may transition the first driving signal DRV1 to a high level. The level of the second driving signal DRV2 is complementary to the level of the first driving signal DRV1, and the waveform of the switching voltage VS is the same as that of the first driving signal DRV1, so the waveform of the second driving signal DRV2 and the waveform of the switching voltage VS are omitted.

As the first driving signal DRV1 transitions to a high level, the first switch SW1 of the switching circuit 110 may be turned on, and the inductor IND or the first capacitor C1 may begin to charge. An inductor current IL of the inductor IND may also begin to increase.

As the first driving signal DRV1 transitions to a high level, the first charging circuit 133 may charge the internal capacitor by using the second voltage V2 to generate the third voltage V3. For example, the first charging circuit 133 may generate a current by using the second voltage V2 and charge the internal capacitor by using the generated current. Accordingly, the third voltage V3 may be a ramp voltage.

At a second time point T2, the third voltage V3 may reach the second reference voltage VREF2. As the third voltage V3 reaches the second reference voltage VREF2, the first comparison circuit 134 may allow a second control signal CS2 to transition from a low level to a high level.

As the second control signal CS2 transitions from a low level to a high level, the control logic 131 may allow the first driving signal DRV1 to transition from a high level to a low level. As the first driving signal DRV1 transitions to a low level, the first switch SW1 of the switching circuit 110 may be turned off, and the inductor IND or the first capacitor C1 may begin to discharge through the turned-on second switch SW2. The inductor current IL may also begin to decrease.

At a third time point T3 and a fourth time point T4, the same operations that occur at the first time point T1 and the second time point T2 may be performed. At a fifth time point T5 and a sixth time point T6, the same operations that occur at the first time point T1 and the second time point T2 may be performed. The voltage converter 100 may convert (or successfully convert) the input voltage VIN into the output voltage VOUT.

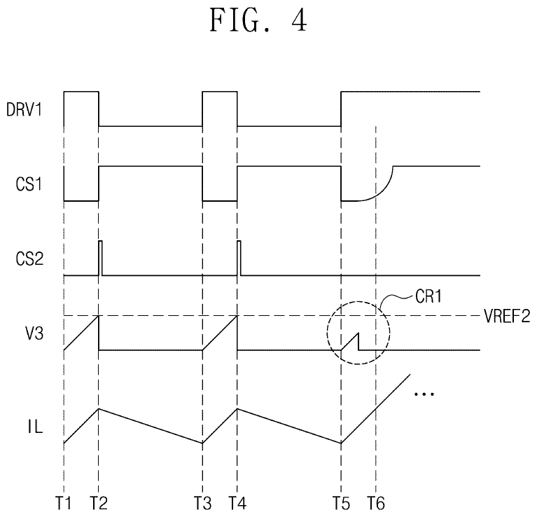

FIG. 4 illustrates a second example of waveforms of signals of the voltage converter 100. For example, an example in which the protection circuit 140 does not operate and the control circuit 130 operates abnormally after normal operation is illustrated in FIG. 4.

Referring to FIGS. 1 and 4, at the first time point T1, the control circuit 130 may transition the first driving signal DRV1 to a high level. The level of the second driving signal DRV2 is complementary to the level of the first driving signal DRV1, and the waveform of the switching voltage VS is the same as that of the first driving signal DRV1, so the waveform of the second driving signal DRV2 and the waveform of the switching voltage VS are omitted.

As the first driving signal DRV1 transitions to a high level, the first switch SW1 of the switching circuit 110 may be turned on, and the inductor IND or the first capacitor C1 may begin to charge. The inductor current IL of the inductor IND may also start to increase.

As the first driving signal DRV1 transitions to a high level, the first charging circuit 133 may charge the internal capacitor by using the second voltage V2 to generate the third voltage V3. For example, the first charging circuit 133 may generate a current by using the second voltage V2 and charge the internal capacitor by using the generated current. Therefore, the third voltage V3 may be a ramp voltage.

At the second time point T2, the third voltage V3 may reach the second reference voltage VREF2. As the third voltage V3 reaches the second reference voltage VREF2, the first comparison circuit 134 may transition the second control signal CS2 from a low level to a high level.

As the second control signal CS2 transitions from a low level to a high level, the control logic 131 may transition the first driving signal DRV1 from a high level to a low level. As the first driving signal DRV1 transitions to a low level, the first switch SW1 of the switching circuit 110 may be turned off, and the inductor IND or the first capacitor C1 may begin to discharge through the turned-on second switch SW2. The inductor current IL may also begin to decrease.

At the third time point T3 and the fourth time point T4, the same operations that occur at the first time point T1 and the second time point T2 may be performed.

At the fifth time point T5, the control circuit 130 may transition the first driving signal DRV1 to a high level. As the first driving signal DRV1 transitions to a high level, the first switch SW1 of the switching circuit 110 may be turned on, and the inductor IND or the first capacitor C1 may begin to charge. The switching voltage VS may also begin to rise.

As the first driving signal DRV1 transitions to a high level, the first charging circuit 133 may charge the internal capacitor by using the second voltage V2 to generate the third voltage V3. For example, the first charging circuit 133 may generate a current by using the second voltage V2 and charge the internal capacitor by using the generated current. Accordingly, the third voltage V3 may be a ramp voltage.

However, the first control signal CS1 may be deactivated (e.g., transitioned to a low level) without the control of the control logic 131. For example, due to noise or malfunction occurring in connection with various operations including a pulse width modulation operation of the control logic 131, the first control signal CS1 may not be activated or may be deactivated without the control of the control logic 131 after being activated.

In some example embodiments, when the first control signal CS1 is deactivated, the first charging circuit 133 may discharge the internal capacitor. Therefore, as indicated by a first circle CR1, the third voltage V3 may increase and then discharge, or may not increase at all. In some example embodiments, when the third voltage V3 does not increase, the third voltage V3 in the first comparison circuit 134 may not reach the second reference voltage VREF2. Therefore, the second control signal CS2 may not transition to a high level and the control logic 131 may maintain the first driving signal DRV1 at a high level. In some example embodiments, when the first driving signal DRV1 is maintained at a high level, the first switch SW1 of the switching circuit 110 may be maintained in a turned-on state, and thus the inductor IND or the first capacitor C1 may be overcharged or an overvoltage may occur in the output voltage VOUT, or an overcurrent may occur in the inductor current IL.

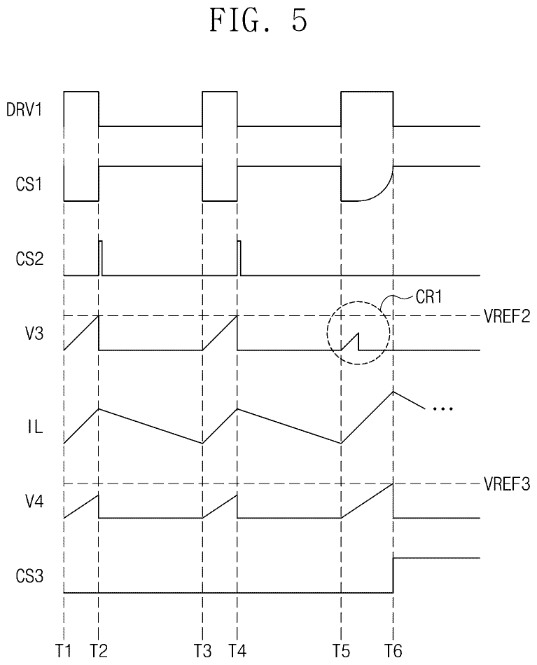

FIG. 5 illustrates a third example of waveforms of signals of the voltage converter 100. For example, an example in which the protection circuit 140 operates when the control circuit 130 operates abnormally after normal operation is illustrated in FIG. 4.

Referring to FIGS. 1 and 5, at the first time point T1, the control circuit 130 may transition the first driving signal DRV1 to a high level. Because the level of the second driving signal DRV2 is complementary to the level of the first driving signal DRV1, and the waveform of the switching voltage VS is the same as that of the first driving signal DRV1, the waveform of the second driving signal DRV2 and the waveform of the switching voltage VS are omitted.

As the first driving signal DRV1 transitions to a high level, the first switch SW1 of the switching circuit 110 may be turned on, and the inductor IND or the first capacitor C1 may begin to charge. The inductor current IL of the inductor IND may also start to rise.

As the first driving signal DRV1 transitions to a high level, the first charging circuit 133 may charge the internal capacitor by using the second voltage V2 to generate the third voltage V3. For example, the first charging circuit 133 may generate a current by using the second voltage V2 and charge the internal capacitor by using the generated current. Therefore, the third voltage V3 may be a ramp voltage.

As the first driving signal DRV1 transitions to a high level, the switching voltage VS may be approximated to the input voltage VIN. The switching voltage VS (or a voltage derived from the switching voltage VS) may be higher than the fourth reference voltage VREF4. Therefore, the third comparison circuit 143 may transition the fourth control signal CS4 to a high level.

As the fourth control signal CS4 transitions to a high level, the first charging circuit 133 may charge the internal capacitor by using the second voltage V2 to generate the fourth voltage V4. For example, the second charging circuit 141 may generate a current by using the second voltage V2 and charge the internal capacitor by using the generated current. Accordingly, the fourth voltage V4 may be a ramp voltage.

At the second time point T2, the third voltage V3 may reach the second reference voltage VREF2. For example, the protection circuit 140 may be implemented to prevent the fourth voltage V4 from reaching the third reference voltage VREF3 when the third voltage V3 reaches the second reference voltage VREF2 (or the protection circuit 140 may be implemented to reduce a probability of the fourth voltage V4 reaching the third reference voltage VREF3 when the third voltage V3 reaches the second reference voltage VREF2). As the third voltage V3 reaches the second reference voltage VREF2, the first comparison circuit 134 may transition the second control signal CS2 from a low level to a high level.

As the second control signal CS2 transitions from a low level to a high level, the control logic 131 may transition the first driving signal DRV1 from a high level to a low level. As the first driving signal DRV1 transitions to a low level, the first switch SW1 of the switching circuit 110 may be turned off, and the inductor IND or the first capacitor C1 may begin to discharge through the turned-on second switch SW2. The inductor current IL may also start to decrease.

As the first driving signal DRV1 transitions from a high level to a low level, the switching voltage VS may be approximated to the ground voltage GND. The switching voltage VS (or a voltage derived from the switching voltage VS) may be lower than the fourth reference voltage VREF4. Accordingly, the third comparison circuit 143 may transition the fourth control signal CS4 to a low level.

For example, the waveform of the fourth control signal CS4 may be approximated to the waveform of the first driving signal DRV1. Therefore, the waveform of the fourth control signal CS4 is omitted.

At the third time point T3 and the fourth time point T4, the same operations that occur at the first time point T1 and the second time point T2 may be performed.

At the fifth time point T5, the control circuit 130 may transition the first driving signal DRV1 to a high level. As the first driving signal DRV1 transitions to a high level, the first switch SW1 of the switching circuit 110 may be turned on, and the inductor IND or the first capacitor C1 may begin to charge. The switching voltage VS may also start to rise.

As the first driving signal DRV1 transitions to a high level, the first charging circuit 133 may charge the internal capacitor by using the second voltage V2 to generate the third voltage V3. For example, the first charging circuit 133 may generate a current by using the second voltage V2 and charge the internal capacitor by using the generated current. Accordingly, the third voltage V3 may be a ramp voltage.

As the first driving signal DRV1 transitions to a high level, the switching voltage VS may be approximated to the input voltage VIN. The switching voltage VS (or a voltage derived from the switching voltage VS) may be higher than the fourth reference voltage VREF4. Accordingly, the third comparison circuit 143 may transition the fourth control signal CS4 to a high level.

As the fourth control signal CS4 transitions to a high level, the first charging circuit 133 may charge the internal capacitor by using the second voltage V2 to generate the fourth voltage V4. For example, the second charging circuit 141 may generate a current by using the second voltage V2 and charge the internal capacitor by using the generated current. Accordingly, the fourth voltage V4 may be a ramp voltage.

For example, the first control signal CS1 may be deactivated (e.g., transitioned to a low level) without the control of the control logic 131. For example, due to noise or malfunction occurring in connection with various operations including a pulse width modulation operation of the control logic 131, the first control signal CS1 may not be activated or may be deactivated without control of the control logic 131 after being activated.

In some example embodiments, when the first control signal CS1 is deactivated, the first charging circuit 133 may discharge the internal capacitor. Therefore, as indicated by the first circle CR1, the third voltage V3 may increase and then discharge, or may not increase at all. In some example embodiments, when the third voltage V3 does not increase, the third voltage V3 in the first comparison circuit 134 may not reach the second reference voltage VREF2. Therefore, the second control signal CS2 may not transition to a high level and the control logic 131 may maintain the first driving signal DRV1 at a high level.

In some example embodiments, when the first driving signal DRV1 is maintained at a high level, the fourth control signal CS4 may also be maintained at a high level. Therefore, the fourth voltage V4 may continuously rise to reach the third reference voltage VREF3. As the fourth voltage V4 reaches the third reference voltage VREF3, the second comparison circuit 142 may transition the third control signal CS3 from a low level to a high level. The level shifter 144 may output the fifth control signal CS5 that corresponds (or complementarily corresponds) to the level of the third control signal CS3.

In some example embodiments, when the fifth control signal CS5 of a low level is received, the logic gate 150 may output the first protected driving signal pDRV1 that turns off the first switch SW1 regardless of the level of the first driving signal DRV1. Therefore, when the fourth voltage V4 reaches the third reference voltage VREF3, the on-stuck of the first switch SW1 may be released.

As described above, the voltage converter 100 according to some example embodiments of the present inventive concepts may include the control circuit 130 that controls the first switch SW1 and the second switch SW2 based on various operations including a pulse width modulation operation. Additionally or alternatively, the voltage converter 100 according to some example embodiments of the present inventive concepts may further include the protection circuit 140 that detects (or simply detects) and protects the on-stuck of the first switch SW1 by using the second voltage V2 of the control circuit 130 and the switching voltage VS without being associated with various operations including a pulse width related operation. Therefore, the stability of the voltage converter 100 is improved.

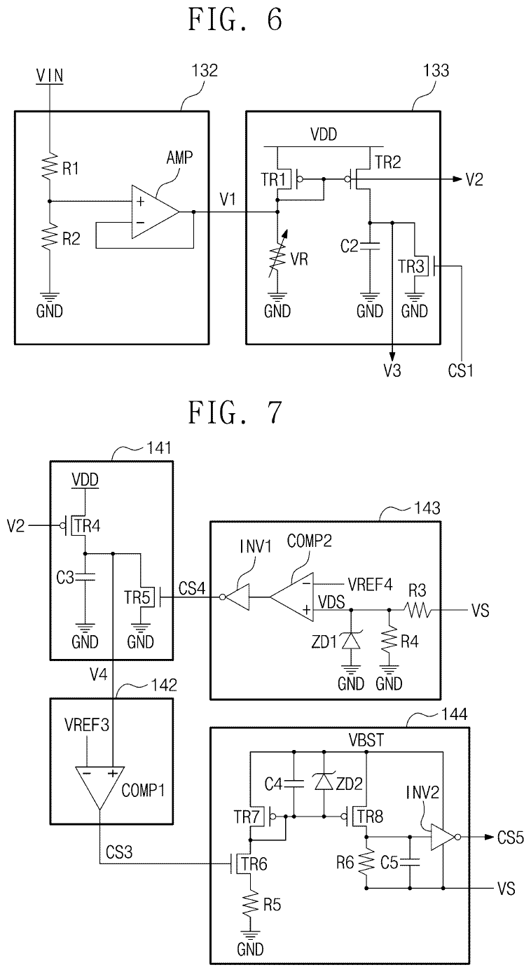

FIG. 6 illustrates the voltage divider 132 and the first charging circuit 133 according to some example embodiments. Referring to FIGS. 1 and 6, the voltage divider 132 may include a first resistor R1, a second resistor R2, and an amplifier AMP. The first resistor R1 and the second resistor R2 may be connected in series between the input node to which the input voltage VIN is input and the ground node to which the ground voltage GND is supplied.

The positive input of the amplifier AMP may be connected to the node between the first resistor R1 and the second resistor R2. The negative input of the amplifier AMP may be connected to the output of the amplifier AMP. For example, the amplifier AMP may form a voltage follower. The output of the amplifier AMP may be the first voltage V1.

The first charging circuit 133 may include a first transistor TR1, a second transistor TR2, a third transistor TR3, a variable resistor VR, and a second capacitor C2.

The first transistor TR1 may include a first terminal connected to a power node to which the power voltage VDD is supplied, a second terminal connected to a node to which the first voltage V1 is supplied, and a gate connected to the second terminal. The voltage at the gate of the first transistor TR1 may be output as the second voltage V2. The variable resistor VR may be connected between a node to which the first voltage V1 is supplied and the ground node to which the ground voltage GND is supplied. The first transistor TR1 and the variable resistor VR may be a current source that generates a current based on the level of the first voltage V1 and the resistance value of the variable resistor VR.

The second transistor may include a first terminal connected to the power node to which the power voltage VDD is supplied, a second terminal connected to the node to which the third voltage V3 is output, and a gate connected to the gate of the first transistor TR1. The voltage of the gate of the second transistor TR2 may be output as the second voltage V2. The second capacitor C2 may be connected between the node to which the third voltage V3 is output and the ground node to which the ground voltage GND is supplied.

The second transistor TR2 may be a current mirror that mirrors the current flowing through the first transistor TR1. The second capacitor C2 may be a capacitor inside the first charging circuit 133 mentioned above, which is charged with the current of the second transistor TR2.

The third transistor TR3 may include a first terminal connected to the node to which the third voltage V3 is supplied, a second terminal connected to the ground node to which the ground voltage GND is supplied, and a gate to which the first control signal CS1 is supplied. The third transistor TR3 may be connected in parallel to the second capacitor C2. In some example embodiments, when the third transistor TR3 is turned off, the second capacitor C2 may be charged with the current of the second transistor TR2, and when the third transistor TR3 is turned on, the second capacitor C2 may be discharged.

FIG. 7 illustrates the second charging circuit 141, the second comparison circuit 142, the third comparison circuit 143, and the level shifter 144 according to some example embodiments.

Referring to FIGS. 1, 6 and 7, the second charging circuit 141 may include a fourth transistor TR4, a fifth transistor TR5, and a third capacitor C3. The fourth transistor TR4 may include a first terminal connected to the power node to which the power voltage VDD is supplied, a second terminal connected to the node to which the fourth voltage V4 is output, and a gate to which the second voltage V2 is supplied. The fourth transistor TR4 may be a current mirror that mirrors the current flowing through the first transistor TR1.

The third capacitor C3 may be connected between the node to which the fourth voltage V4 is output and the node to which the ground voltage GND is supplied. The third capacitor C3 may be a capacitor inside the second charging circuit 141 mentioned above, which is charged with the current of the fourth transistor TR4.

The fifth transistor TR5 may include a first terminal connected to the node to which the fourth voltage V4 is output, a second terminal connected to the ground node to which the ground voltage GND is supplied, and a gate to which the fourth control signal CS4 is supplied. The fifth transistor TR5 may be connected in parallel to the third capacitor C3. In some example embodiments, when the fifth transistor TR5 is turned off, the third capacitor C3 may be charged with the current of the fourth transistor TR4, and when the fifth transistor TR5 is turned on, the third capacitor C3 may be discharged.

The second comparison circuit 142 may include a first comparator COMP1. The first comparator COMP1 may include a positive input to which the fourth voltage V4 is transmitted and a negative input to which the third reference voltage VREF3 is transmitted. The first comparator COMP1 may output the third control signal CS3 of a high level when the fourth voltage V4 is equal to or higher than the third reference voltage VREF3. The first comparator COMP1 may output the third control signal CS3 of a low level when the fourth voltage V4 is lower than the third reference voltage VREF3.

The third comparison circuit 143 may include a third resistor R3, a fourth resistor R4, a first Zener diode ZD1, a second comparator COMP2, and a first inverter INV1. The third resistor R3 is connected between the node to which the switching voltage VS is input and the positive input of the second comparator COMP2. The fourth resistor R4 is connected between the positive input of the second comparator COMP2 and the ground node to which the ground voltage GND is transmitted. The third resistor R3 and the fourth resistor R4 may divide the switching voltage VS and transmit it (e.g., the divided voltage) to the positive input of the second comparator COMP2 as a divided switching voltage VDS. For example, the divided switching voltage VDS may be included in the voltage derived from the switching voltage VS.

The first Zener diode ZD1 is connected between the positive input of the second comparator COMP2 and the ground node to which the ground voltage GND is transmitted. The first Zener diode ZD1 may prevent the divided switching voltage VDS of the positive input of the second comparator COMP2 from overshooting (or the first Zener diode ZD1 may reduce a probability that the divided switching voltage VDS of the positive input of the second comparator COMP2 overshoots).

The second comparator COMP2 may include the positive input to which the divided switching voltage VDS is transmitted, and the negative input to which the fourth reference voltage VREF4 is transmitted. The second comparator COMP2 may output a positive voltage when the divided switching voltage VDS is higher than the fourth reference voltage VREF4. The second comparator COMP2 may output a negative voltage when the divided switching voltage VDS is equal to or lower than the fourth reference voltage VREF4.

The first inverter INV1 may invert the output voltage of the second comparator COMP2 and output it as the fourth control signal CS4. For example, the first inverter INV1 may output the positive fourth control signal CS4 when the divided switching voltage VDS is equal to or higher than the fourth reference voltage VREF4. The second comparator COMP2 may output the negative fourth control signal CS4 when the divided switching voltage VDS is lower than the fourth reference voltage VREF4.

The level shifter 144 may include a sixth transistor TR6, a seventh transistor TR7, an eighth transistor TR8, a fifth resistor R5, a fourth capacitor C4, a fifth capacitor C5, a second Zener diode ZD2, and a second inverter INV2.

The sixth transistor TR6 may include a first terminal connected to the seventh transistor TR7, a second terminal connected to the fifth resistor R5, and a gate to which the third control signal CS3 is transmitted. The seventh transistor TR7 may include a first terminal connected to a node to which a bootstrap voltage VBST is transmitted, a second terminal connected to the first terminal of the sixth transistor TR6, and a gate connected to the second terminal of the seventh transistor TR7. The fifth resistor R5 may be connected between the second terminal of the sixth transistor TR6 and the ground node to which the ground voltage GND is transmitted.

The seventh transistor TR7 may be a current source that is activated or deactivated by the sixth transistor TR6 and generates a positive current determined by the fifth resistor R5.

The eighth transistor TR8 may include a first terminal connected to a node to which the bootstrap voltage VBST is transmitted, a second terminal connected to the sixth resistor R6, and a gate connected to the gate of the seventh transistor TR7. The sixth resistor R6 may be connected between the gate of the eighth transistor TR8 and the node to which the switching voltage VS is transmitted. The eighth transistor TR8 may be a current mirror that mirrors the current of the seventh transistor TR7. The eight resistor R8 may generate a voltage higher than the switching voltage VS at the second terminal of the eighth transistor TR8.

The fourth capacitor C4 may be connected between the node to which the bootstrap voltage VBST is transmitted and the gate of the seventh transistor TR7. The fourth capacitor C4 may provide a voltage difference between the node to which the bootstrap voltage VBST is transmitted and the voltage of the gate of the seventh transistor TR7. In some example embodiments, when the seventh transistor TR7 conducts current, the voltage of the gate of the seventh transistor TR7 may be determined by the fifth resistor. Depending on (or based on) the direction of current flow in the fourth capacitor C4 and the seventh transistor TR7, the bootstrap voltage VBST may be formed to be higher than the voltage of the gate of the seventh transistor TR7.

The second Zener diode ZD2 may be connected between the node to which the bootstrap voltage VBST is transmitted and the gate of the seventh transistor TR7. The second Zener diode ZD2 may prevent the bootstrap voltage VBST from overshooting (or the second Zener diode ZD2 may reduce a probability that the bootstrap voltage VBST overshoots).

The fifth capacitor C5 may be connected between the second terminal of the eighth transistor TR8 and the node to which the switching voltage VS is transmitted. The fifth capacitor C5 may remove high-frequency noise from the voltage of the second terminal of the eighth transistor TR8.

The second inverter INV2 may be biased by the bootstrap voltage VBST and the switching voltage VS. The second inverter INV2 may output the level of the switching voltage VS as the low level of the fifth control signal CS5, and output the level of the bootstrap voltage VBST as the high level of the fifth control signal CS5.

The level shifter 144 may be a current type level shifter. The level shifter 144 may be activated when the third control signal CS3 becomes a high level, but may ensure (or may cause) a low level corresponding to the switching voltage VS and a high level corresponding to the bootstrap voltage VBST, and may ensure that (or may cause that) the first switch SW1 of the switching circuit 110 is turned off by outputting a low level.

For example, the first charging circuit 133 and the second charging circuit 141 may charge the first capacitor C1 and the second capacitor C2 by using the same voltage (e.g., the first voltage V1 or the second voltage V2). However, from the same level, it is illustrated that the time for the third voltage V3 to reach the second reference voltage VREF2 is faster than the time for the fourth voltage V4 to reach the third reference voltage VREF3. This may be implemented in various manners.

As an example, the current amount of the fourth transistor TR4 of the second charging circuit 141 may be implemented to be less than the current amount of the second transistor TR2 of the first charging circuit 133. For example, the size of the fourth transistor TR4 of the second charging circuit 141, for example, the channel width, may be implemented to be smaller than the size of the second transistor TR2 of the first charging circuit 133, for example, the channel width.

As an example, the capacity of the second capacitor C2 of the second charging circuit 141 may be implemented to be less than the capacity of the first capacitor C1 of the first charging circuit 133.

As an example, the third reference voltage VREF3 may be implemented to be higher than the second reference voltage VREF2.

As an example, the three examples mentioned above, and at least two or more of the other additional examples, may be implemented in combination.

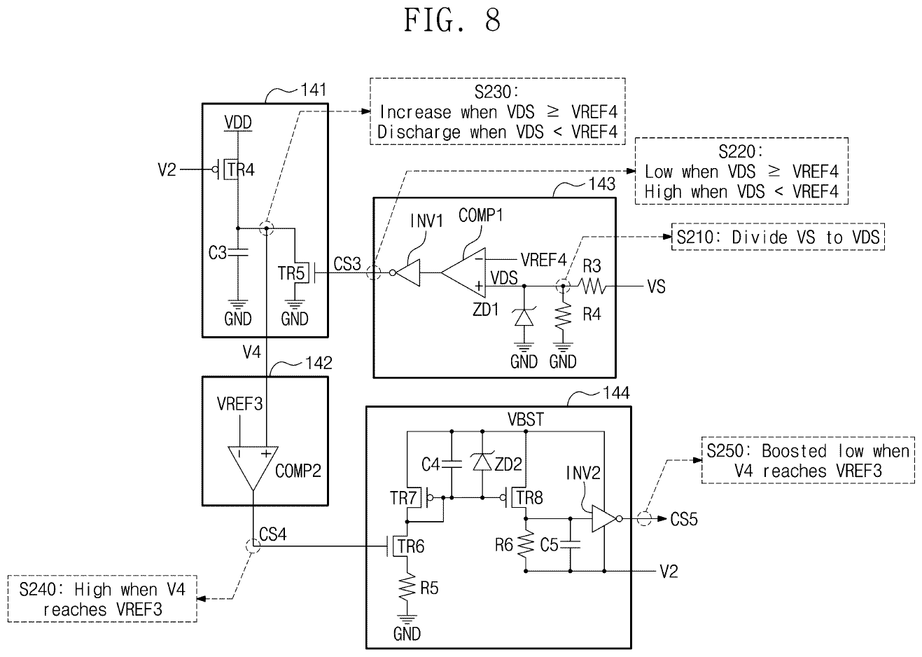

FIG. 8 illustrates an example of a method of operating the second charging circuit 141, the second comparison circuit 142, the third comparison circuit 143, and the level shifter 144 according to some example embodiments. Referring to FIGS. 1 and 8, in operation S210, the third comparison circuit 143 may divide the switching voltage VS into the divided switching voltage VDS.

In operation S220, the third comparison circuit 143 may output the third control signal CS3 of a low level when the divided switching voltage VDS is equal to or higher than the fourth reference voltage VREF4, and may output the third control signal CS3 of a high level when the divided switching voltage VDS is lower than the fourth reference voltage VREF4.

In operation S230, the second charging circuit 141 may increase the fourth voltage V4 when the divided switching voltage VDS is equal to or higher than the fourth reference voltage VREF4, and discharge (or reduce) the fourth voltage V4 when the divided switching voltage VDS is lower than the fourth reference voltage VREF4.

In operation S240, the second comparison circuit 142 may output the fourth control signal CS4 of a high level when the fourth voltage V4 reaches the third reference voltage VREF3.

In operation S250, the level shifter 144 may output the fifth control signal CS5 of a boosted low level when the fourth voltage V4 reaches the third reference voltage VREF3.

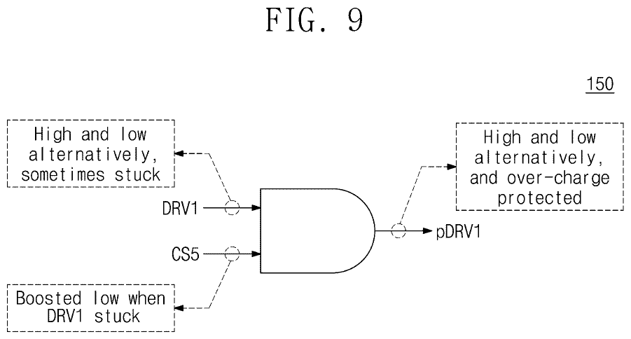

FIG. 9 illustrates an example of the logic gate 150 according to some example embodiments. Referring to FIGS. 1 and 9, the logic gate 150 may perform an AND operation of the first driving signal DRV1 and the fifth control signal CS5. The first driving signal DRV1 may alternately have a high level and a low level and may occasionally be on-stuck. The fifth control signal CS5 may have a boosted low level when the first driving signal DRV1 is stuck (e.g., on-stuck).

Through the AND operation of the first driving signal DRV1 and the fifth control signal CS5, the first protected driving signal pDRV1 may alternately have a high level and a low level, thereby protecting against overcharge.

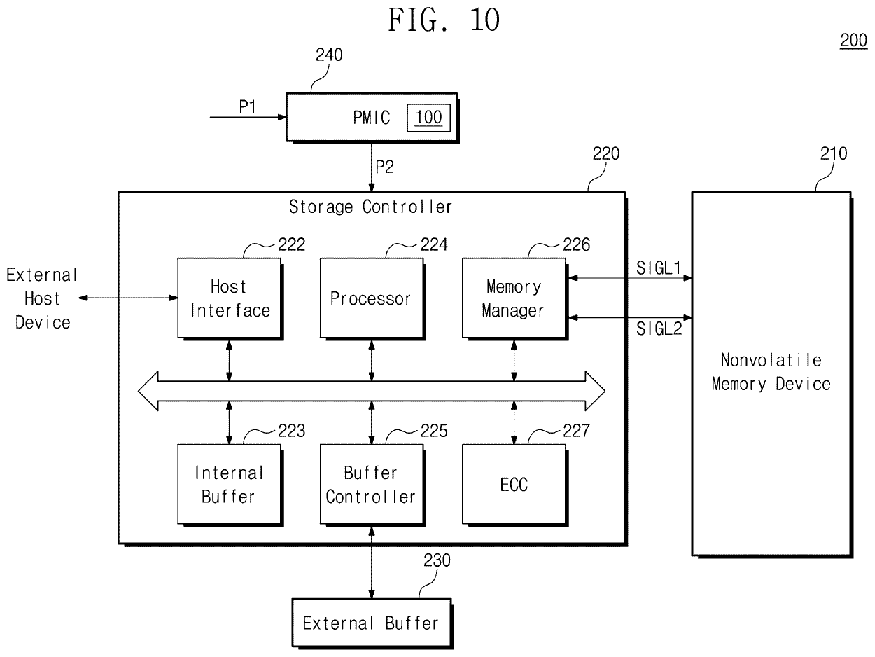

FIG. 10 illustrates a storage device 200 according to some example embodiments. Referring to FIG. 10, the storage device 200 may include a nonvolatile memory device 210, a storage controller 220, an external buffer 230, and a power management integrated circuit (PMIC) 240.

The nonvolatile memory device 210 may include a plurality of memory cells. Each memory cell of the plurality of memory cells may store two or more bits. For example, the nonvolatile memory device 210 may include at least one of various nonvolatile memory devices, such as a flash memory device, a phase change memory device, a ferroelectric memory device, a magnetic memory device, a resistive memory device, and the like, but example embodiments are not limited thereto.

The storage controller 220 may receive various requests from an external host device to write data to the nonvolatile memory device 210 or to read data from the nonvolatile memory device 210. The storage controller 220 may store (or buffer) user data communicated with an external host device in the external buffer 230, and store metadata for managing the storage device 200 in the external buffer 230.

The storage controller 220 may access the nonvolatile memory device 210 through first signal lines SIGL1 and second signal lines SIGL2. For example, the storage controller 220 may transmit commands and addresses to the nonvolatile memory device 210 through the first signal lines SIGL1. The storage controller 220 may exchange data with the nonvolatile memory device 210 through the first signal lines SIGL1.

The storage controller 220 may transmit a first control signal to the nonvolatile memory device 210 through the second signal lines SIGL2. The storage controller 220 may receive a second control signal from the nonvolatile memory device 210 through the second signal lines SIGL2.

For example, the storage controller 220 may be configured to control two or more nonvolatile memory devices. The storage controller 220 may have different first signal lines and different second signal lines for each of two or more nonvolatile memory devices.

As another example, the storage controller 220 may share the first signal lines for two or more nonvolatile memory devices. The storage controller 220 may share some of the second signal lines for two or more nonvolatile memory devices and provide the remaining lines separately.

The external buffer 230 may include a random access memory. For example, the external buffer 230 may include at least one of a dynamic random access memory, a phase change random access memory, a ferroelectric random access memory, a magnetic random access memory, and a resistive random access memory, but example embodiments are not limited thereto.

The storage controller 220 may include a bus 221, a host interface 222, an internal buffer 223, a processor 224, a buffer controller 225, a memory manager 226, and an error correction code (ECC) block 227.

The bus 221 may provide communication channels between components within the storage controller 220. The host interface 222 may receive various requests from an external host device and interpret the received requests. The host interface 222 may store interpreted requests in the internal buffer 223.

The host interface 222 may transmit various responses to an external host device. The host interface 222 may exchange signals with an external host device based on a specified communication protocol. The internal buffer 223 may include a random access memory. For example, the internal buffer 223 may include a static random access memory or a dynamic random access memory.

The processor 224 may drive an operating system or firmware to drive the storage controller 220. The processor 224 may read the interpreted requests stored in the internal buffer 223 and generate commands and addresses for controlling the nonvolatile memory device 210. The processor 224 may transfer the generated commands and addresses to the memory manager 226.

The processor 224 may store various metadata for managing the storage device 200 in the internal buffer 223. The processor 224 may access the external buffer 230 through the buffer controller 225. The processor 224 may control the buffer controller 225 and the memory manager 226 to transmit user data stored in the external buffer 230 to the nonvolatile memory device 210.

The processor 224 may control the host interface 222 and the buffer controller 225 to transmit data stored in the external buffer 230 to an external host device. The processor 224 may control the buffer controller 225 and the memory manager 226 to store data received from the nonvolatile memory device 210 in the external buffer 230. The processor 224 may control the host interface 222 and the buffer controller 225 to store data received from an external host device in the external buffer 230.

The buffer controller 225 may write data to the external buffer 230 or read data from the external buffer 230 under the control of the processor 224. The memory manager 226 may communicate with the nonvolatile memory device 210 through the first signal lines SIGL1 and the second signal lines SIGL2 under the control of the processor 224.

The memory manager 226 may access the nonvolatile memory device 210 under the control of the processor 224. For example, the memory manager 226 may access the nonvolatile memory device 210 through the first signal lines SIGL1 and the second signal lines SIGL2. The memory manager 226 may communicate with the nonvolatile memory device 210 based on a protocol defined by a standard or specified by the manufacturer.

The error correction code block 227 may perform error correction encoding by using an error correction code (ECC) on data transmitted to the nonvolatile memory device 210. The error correction code block 227 may perform error correction decoding on data received from the nonvolatile memory device 210 by using an error correction code (ECC).

For example, the external buffer 230 and the buffer controller 225 may be omitted from the storage device 200. In some example embodiments, when the external buffer 230 and the buffer controller 225 are omitted, the functions described as being performed by the external buffer 230 and the buffer controller 225 may be performed by the internal buffer 223.

The PMIC 240 may receive first power P1 from an external host device. The PMIC 240 may generate second power P2 based on the first power P1 and provide the second power P2 to the storage controller 220. For example, the voltage of the second power P2 may be lower than the voltage of the first power P1.

The PMIC 240 may include the voltage converter 100 for reducing (or stepping down) the voltage of the first power P1 to the voltage of the second power P2. The voltage converter 100 may be configured and operated in the same manner as described with reference to FIGS. 1 to 9.

For example, the voltage converter 100 may reduce (or step down) the voltage of the first power P1 to the voltage of the second power P2 by controlling switches based on pulse width modulation. The voltage converter 100 may detect the stuck of the switches based on the levels of the voltages of the voltage converter 100 without depending on pulse width modulation.

Accordingly, the voltage of the first power P1 supplied by the PMIC 240 to the storage controller 220 is prevented from being overvoltage due to overcharging, and the storage controller 220 is prevented from being damaged (or a probability that the voltage of the first power P1 supplied by the PMIC 240 to the storage controller 220 is over a desired voltage (e.g., overvoltage) due to overcharging may be reduced, and a probability that the storage controller 220 is damaged may be reduced).

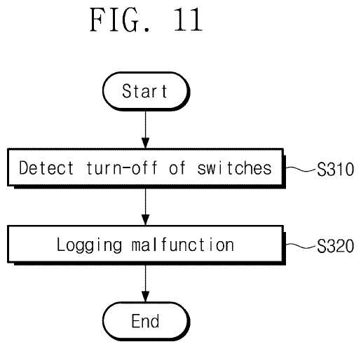

FIG. 11 illustrating an example of a method of operating the storage device 200 according to some example embodiments. Referring to FIGS. 10 and 11, in operation S310, the storage device 200 may detect the turn-off of the switches of the voltage converter 100. For example, the storage controller 220 or the PMIC 240 of the storage device 200 may detect that the operation of the voltage converter 100 stops.

For example, the voltage converter 100 may turn off the first switch and stop operation of the voltage converter 100 when (or in response to) overcharge or overvoltage is detected (or being detected). The storage controller 220 or the PMIC 240 may detect the voltage converter 100 (or voltage converters) that stops operating due to overcharge or overvoltage.

In some example embodiments, when it is detected that the voltage converter 100 stops operating, in operation S320, the storage device 200 may log the malfunction. For example, the storage controller 220 or the PMIC 240 may log the malfunction of the voltage converter 100 in at least one register therein. At least one register therein may be accessible via at least one of various channels, such as a normal channel, a sideband channel, or a debugging channel. Therefore, the operational defect of the voltage converter 100 may be analyzed clearly (or more clearly).

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FGPA), a System-on-Chip (SoC), a programmable logic unit, a microprocessor, application-specific integrated circuit (ASIC), etc.

In the above-described example embodiments, components according to the technical spirit of the present inventive concepts have been described using terms such as first, second, and third. However, terms such as “first”, “second”, “third”, and the like are used to distinguish components from each other and do not limit the present disclosure. For example, terms such as “first”, “second”, “third”, and the like do not imply order or numerical meaning in any form.

In the example embodiments described above, components according to some example embodiments are referenced using blocks. The blocks may be implemented as various hardware devices, such as integrated circuits (ICs), application specific ICs (ASICs), field programmable gate arrays (FPGAs), or complex programmable logic devices (CPLDs), software such as firmware or applications that run on hardware devices, or a combination of hardware devices and software. Additionally or alternatively, the blocks may include circuits including semiconductor elements within an IC or circuits registered as intellectual property (IP).

Some example embodiments have been described above. The present inventive concepts may include not only the above-described example embodiments, but also simple design changes or easily changeable example embodiments. Additionally or alternatively, the present inventive concepts may include techniques that may easily modify and implement the example embodiments. Therefore, the scope of the present inventive concepts should not be limited to the above-described example embodiments, but should be defined by the claims described below as well as the claims and equivalents.

What is claimed is:

1. A voltage converter comprising:
a first switch between an input voltage node and a switching node, the input voltage node configured to receive an input voltage;
a second switch between the switching node and a ground node, the ground node configured to receive a ground voltage;
an inductor between the switching node and an output node;
a capacitor between the inductor and the ground node;
a control circuit configured to control the first switch and the second switch to output an output voltage through the output node, the output voltage being lower than the input voltage; and
a protection circuit configured to turn off the first switch in response to the first switch being turned on for a period of time that is longer than a desired period of time.

2. The voltage converter of claim 1, wherein the control circuit is configured to
charge a first capacitor using a first voltage while a first control signal is activated after the first switch is turned on, and
turn off the first switch in response to a voltage of the first capacitor reaching a first reference voltage.

3. The voltage converter of claim 2, wherein the protection circuit is configured to
charge a second capacitor using the first voltage while a second control signal is activated after the first switch is turned on, and
turn off the first switch in response to a voltage of the second capacitor reaching a second reference voltage.

4. The voltage converter of claim 3, wherein an amount of current charged to the second capacitor by the protection circuit is less than an amount of current charged to the first capacitor by the control circuit.

5. The voltage converter of claim 3, wherein a capacity of the second capacitor is less than a capacity of the first capacitor.

6. The voltage converter of claim 3, wherein the second reference voltage is higher than the first reference voltage.

7. The voltage converter of claim 3, wherein the control circuit includes:
a current generator configured to generate a first current using the first voltage;
a current mirror configured to mirror the first current into a second current by using the first voltage; and
a first transistor connected in parallel with the first capacitor;
wherein the first capacitor is configured to receive the second current, and
wherein the first transistor is configured to
turn off in response to the first control signal being activated, and
turn on in response to the first control signal being deactivated.

8. The voltage converter of claim 7, wherein the protection circuit includes:
a current mirror configured to mirror the first current into a third current by using the first voltage; and
a second transistor connected in parallel with the second capacitor,
wherein the second capacitor is configured to receive the third current; and
wherein the second transistor is configured to
turn off in response to the second control signal being activated, and
turn on in response to the second control signal being deactivated.

9. The voltage converter of claim 8, wherein the protection circuit further includes:
a comparator configured to compare the voltage of the second capacitor with the second reference voltage; and
a level shifter configured to convert an output signal of the comparator into a voltage that swings between a bootstrap voltage and a voltage of the switching node.

10. The voltage converter of claim 8, wherein the protection circuit further includes a comparison circuit configured to
divide a voltage of the switching node to generate a distribution switch voltage, and
compare the distribution switch voltage with a third reference voltage to provide the second control signal.

11. The voltage converter of claim 3, further comprising:
a logic circuit configured to
receive a first signal output by the control circuit for controlling the first switch and a second signal output by the protection circuit for controlling the first switch, and
transmit a result of a logical product operation of the first signal and the second signal to the first switch.

12. The voltage converter of claim 1, wherein the protection circuit is configured to turn off the first switch by using a voltage used in the control circuit and a voltage of the switching node.

13. A method of operating a voltage converter, the method comprising:
controlling, by a control circuit of the voltage converter, a first switch and a second switch to convert an input voltage supplied to a first terminal of the first switch into an output voltage output to an output node between an inductor and a capacitor; and
turning off, by a protection circuit of the voltage converter, the first switch in response to an overcharge of the output voltage being detected.

14. The method of claim 13, wherein the turning off of the first switch includes:
generating a distribution switching voltage by dividing a voltage of a switching node; and
detecting the overcharge by detecting a length of time for which the distribution switching voltage is higher than a first reference voltage.

15. The method of claim 14, wherein the detecting of the overcharge includes:
generating a current by using a voltage transmitted from the control circuit during a time for which the distribution switching voltage is higher than the first reference voltage;
charging the capacitor of the protection circuit by using the current; and
turning off the first switch in response to a voltage of the capacitor reaching a second reference voltage.

16. The method of claim 13, wherein the turning off of the first switch includes transmitting a low level signal, the low level signal having a voltage biased between a voltage of a switching node and the input voltage to the first switch.

17. The method of claim 13, wherein the turning off of the first switch includes detecting the overcharge by using a voltage transmitted from the control circuit and a voltage of a switching node.

18. A storage device comprising:
a nonvolatile memory device;
a storage controller configured to control the nonvolatile memory device; and
a power management integrated circuit (PMIC) configured to supply power to the storage controller,
wherein the PMIC includes
a first switch between an input voltage node and a switching node, the input voltage node configured to receive an input voltage;
a second switch between the switching node and a ground node, the ground node configured to receive a ground voltage;
an inductor between the switching node and an output node;
a capacitor between the inductor and the ground node;
a control circuit configured to control the first switch and the second switch to output an output voltage through the output node, the output voltage being lower than the input voltage; and
a protection circuit configured to turn off the first switch in response to the first switch being turned on for a period of time that is longer than a desired period of time.

19. The storage device of claim 18, wherein at least one of the storage controller and the PMIC is configured to log a malfunction of the PMIC in response to the first switch being turned off by the protection circuit.

20. The storage device of claim 18, wherein the PMIC is configured to stop an overvoltage or an overcurrent from being supplied to the storage controller based on turning off the first switch using the protection circuit.
